(19) United States
(12) Patent Application Publication
(10) Pub. No.: US 2006/0269015 A1
(43) Pub. Date: Nov. 30, 2006

(54) Receivers for DPSK signals

(75) Inventors: Tingwu Wang, Singapore (SG); Ju Yan Pan, Singapore (SG); Zhiyong Xiao, Singapore (SG); Yu Jing Ting, Singapore (SG); Yang Yu, Singapore (SG)

Correspondence Address: QUARLES & BRADY LLP, 411 E. WISCONSIN AVENUE, SUITE 2040, MILWAUKEE, WI, 53202-4497, US

(73) Assignee: Oki Techno Centre ( Singapore) Pte Ltd

(21) Appl. No.: 11/439,326

(22) Filed: May 23, 2006

(30) Foreign Application Priority Data
May 24, 2005 (SG) 200503280-0

(51) Int. Cl. H04L 27/22; H03D 1/04; H04L 7/00

(52) U.S. Cl. 375/330; 375/365; 375/346

(57) ABSTRACT

There is provided an apparatus and method for performing unique word detection and frequency offset estimation for a receiver for DPSK signals comprising in-phase I and quadrature Q components for a plurality of symbols k. The apparatus comprises: a differential detector for performing differential detection of a received signal over a given symbol span; a frequency corrector for performing an initial correction of I and Q using a previously estimated value of the frequency offset; accumulators for averaging I and Q for each symbol k over a given number K of symbols, where K is the number of symbols in the unique word to be detected; a frequency offset estimation block for calculating an estimate of the frequency offset from averaged I and averaged Q; and a unique word detection block for determining, from differentially detected I, differentially detected Q, averaged I and averaged Q, whether or not the unique word is present in a received signal.

### FIELD OF THE INVENTION

The invention relates to performing unique word detection and frequency offset estimation in a receiver for DPSK signals. In particular, the invention relates to an apparatus and method for performing both unique word detection and frequency offset estimation.

### BACKGROUND OF THE INVENTION

Phase Shift Keying (PSK) and Differential Phase Shift Keying (DPSK) modulation schemes are widely used in wireless communication. In DPSK, the phase of the carrier is discretely varied in relation to the phase of the immediately preceding signal element and in accordance with the data being transmitted. Differential Quadrature Phase Shift Keying (DQPSK) and Differential Bi-Phase Shift Keying (DBPSK) are other variations.

Two important processes in demodulation at the receiver side are residual frequency offset estimation and UW (unique word) detection.

Regarding frequency offset estimation, when receiving and de-modulating a digitally modulated signal, an estimated replica of the received carrier frequency is used to recover the signal. Ideally, the transmitter generates a carrier signal that exists at some known frequency and the received signals are then demodulated at the receiver using the same known frequency. However, inaccuracies in the transmitter and receiver oscillators, along with the effect of Doppler Shifting, result in carrier frequency offsets. If the frequency offset is excessive and not suitably compensated for, the performance of the demodulator will be degraded and the original signal may not be recoverable. In frequency offset estimation, an estimate of the frequency offset error is made and used in frequency offset error correction and/or compensation, so as to compensate for the frequency difference between transmitted and received carriers.

Regarding UW detection, the UW in a slot is a portion of the slot used for synchronization and/or identification. UW detection is popular in TDMA burst communication systems. The UW is typically around 5% to 10% of the slot length. Detecting the UW symbols enables the receiver to ascertain the type of slot and to synchronize the symbol timing.

The system described in “Personal Handy Phone System”, ARIB Standard, Version 4.0, February 2003, uses

$$\frac{π}{4}$$

DQPSK modulation to achieve 32 kbps in each slot. In a more advanced version (Advanced Personal Handy Phone System) 16 QAM (16-state Quadrature Amplitude Modulation) and 64 QAM (64-state Quadrature Amplitude Modulation) are introduced to increase the transmission rate from 32 kbps to 64 kbps and 96 kbps respectively.

The slot structure for the Advanced Personal Handy Phone System is shown in FIG. 1. The slot comprises a first portion which is

$$\frac{π}{4}$$

DQPSK modulated, comprising a preamble and UW, and a second portion which is

$$\frac{π}{4}$$

DQPSK and/or QAM modulated, comprising the information stream itself and a number of GT (Guard Time) symbols. The GT symbols represent a portion of the slot where nothing is being transmitted; this helps combat the problem of inter symbol interference. The receiver usually performs quick algorithms to demodulate the burst slots and the use of QAM symbols in the information stream means that a more accurate demodulation is required since QAM (particularly 64 QAM) is rather sensitive to errors in frequency offset estimation.

FIG. 2 shows a known way to estimate and correct the frequency offset, as described in Proakis, Digital Communications, “Chapter 6: Carrier and symbol synchronization,” McGraw-Hill International Editions, Singapore, 3^{rd} edition, 1995.

The received signal is represented by Iᵣ and Qᵣ, Iᵣ being the in-phase component and Qᵣ being the quadrature component. Block 201 performs differential detection of one symbol span, with each symbol having an order k, i.e.
I_{d}(k)=Iᵣ(k)Iᵣ(k−1)+Qᵣ(k)Qᵣ(k−1) [1]
Q_{d}(k)=Qᵣ(k)Iᵣ(k−1)−Iᵣ(k)Qᵣ(k−1) [2]

Block 203 performs a frequency correction using a previously estimated value of the frequency offset Δ_{f}′ (using a frequency offset estimation algorithm) to compensate for the differential detection output. That is, this correction is performed on the differential detection outputs which contain frequency offset error. The correction at block 203 is a first stage of frequency offset error correction.
I_{c}(k)=I_{d}(k)cos φ+Q_{d}(k)sin φ [3]
Q_{c}(k)=Q_{d}(k)cos φ−I_{d}(k)sin φ [4]
where φ=2πΔ_{f}′k.

Block 205 uses hard decisions for the I and Q signals to rotate I_{c} and Q_{c} towards the x-axis of the first quadrant. This decision-based rotation block may or may not be included.

Block 207 is an accumulation block and performs the summing up of the I and Q signals:

$$\begin{matrix}{I}_{a} = {\sum }_{0}^{K - 1} {I}_{h} & [ 5 ] \\ {Q}_{a} = {\sum }_{0}^{K - 1} {Q}_{h} & [ 6 ]\end{matrix}$$

where K is the number of symbols used for the frequency estimation. Because the symbols are spread around the x-axis, summing up the I and Q actually gives an average I and an average Q. (If there is no rotation block 205, the accumulation block will sum I_{c} and Q_{c}.)

Block 209 is an arctan computation block and computes the angle formed by the average I and the average Q from equations [5] and [6]. Since tan of each angle is

$$\frac{Q}{I} ,$$

we have for the summed I and the summed Q, an average angle with respect to the x-axis of:

$$arctan [ \frac{{Q}_{a}}{{I}_{a}} ] \qquad [ 7 ]$$

This angle corresponds to the secondary frequency offset error Δ_{f}″ which was not used for correction at block 203.

Block 211 is a frequency offset calculation block and updates the frequency error offset, to produce an improved estimate Δ_{f}′ᵢₘₚ, by adding the secondary frequency offset error from the computed average angle i.e.
Δ_{f}′ᵢₘₚ=Δ_{f}′+Δ_{f}″ [8]

Δ_{f}″ is smaller than Δ_{f}′ so this update represents a fine tuning of the correction already made at block 203.

FIG. 3 shows the known basic structure for UW detection. The general idea is to compare known UW bits with the received sample and hence decide whether or not UW is present. Referring to FIG. 3, the received signal is again represented by Iᵣ and Qᵣ. Block 301 uses a comparison algorithm to compare the received Iᵣ and Qᵣ with known UW bits. The comparison algorithm is usually a bit to bit comparison or symbol to symbol comparison. Block 303 makes the decision as to whether UW is present or not. The decision making is usually a threshold comparison function.

FIGS. 2 and 3 show the prior art arrangements for frequency error estimation and UW detection respectively. It can be seen that frequency estimation and UW detection take up a considerable amount of demodulation resources and any implementation which would reduce complexity and allow more demodulation resources to be spent on the demodulation itself would be useful.

### SUMMARY OF THE INVENTION

It is an object of the invention to provide an apparatus and method, which mitigate or substantially overcome the problems of prior art arrangements described above. It is a further object of the invention to provide an apparatus and method for performing both frequency offset estimation and unique word detection.

According to a first aspect of the invention, there is provided apparatus for performing unique word detection and frequency offset estimation for a receiver for DPSK signals comprising in-phase I and quadrature Q components for a plurality of symbols k, the apparatus comprising:

a differential detector for performing differential detection of a received signal over a given symbol span;

a frequency corrector for performing an initial correction of I and Q using a previously estimated value of the frequency offset;

an accumulator for averaging I for each symbol k over a given number K of symbols, where K is the number of symbols in the unique word to be detected;

an accumulator for averaging Q for each symbol k over the given number K of symbols;

a frequency offset estimation block for calculating an estimate of the frequency offset from averaged I and averaged Q; and

a unique word detection block for determining, from differentially detected I, differentially detected Q, averaged I and averaged Q, whether or not the unique word is present in a received signal.

The differential detector, the frequency corrector and the accumulators are shared between the functions of the frequency offset estimation and the unique word detection. The final stages of the frequency offset estimation and the unique word detection are performed in the frequency offset estimation block and the unique word detection block respectively. This greatly simplifies the construction.

Typically, the differential detector will perform differential detection over a symbol span of one symbol.

Typically, the previously estimated value of the frequency offset will have been estimated using a frequency offset estimation algorithm.

The frequency offset estimation block may comprise: a computation block for calculating the angle formed by averaged I and averaged Q; and a frequency offset calculation block for calculating the estimate of the frequency offset from the angle formed by averaged I and averaged Q.

Preferably, the computation block performs the arctan function for calculating the angle formed by averaged I and averaged Q. The computation block may perform the arctan function using, for example, a CORDIC (Coordinate Rotation Digital Computer) algorithm or a Look Up Table (LUT) algorithm.

The unique word detection block preferably comprises:

a first portion for generating a first factor dependent on differentially detected I and differentially detected Q;

a second portion for generating a second factor dependent on averaged I and averaged Q; and

a comparator for comparing the first factor and the second factor to determine whether the unique word is present in the received signal.

Because K is the number of unique word symbols, the unique word detection block effectively looks at each received sequence of K symbols and determines whether or not this sequence is equal to the unique word and therefore determines whether or not the unique word is present.

In one embodiment, the first factor is dependent on the square of differentially detected I and the square of differentially detected Q and the second factor is dependent on the square of averaged I and the square of averaged Q.

The first factor may equal the summation over K symbols of the sum of the square of differentially detected I and the square of differentially detected Q. In that case, the first portion of the unique word detection block may comprise a first block for squaring differentially detected I, a second block for squaring differentially detected Q, an addition block for adding the square of differentially detected I and the square of differentially detected Q and an accumulation block for performing the summation over K symbols of the sum of the square of differentially detected I and the square of differentially detected Q.

The second factor may equal the sum of the square of averaged I and the square of averaged Q. In that case, the second portion of the unique word detection block may comprise a first block for squaring averaged I, a second block for squaring averaged Q and an addition block for adding the square of averaged I and the square of averaged Q.

In an alternative embodiment, the first factor is dependent on the absolute value of differentially detected I and the absolute value of differentially detected Q and the second factor is dependent on the absolute value of averaged I and the absolute value of averaged Q.

The first factor may equal the summation over K symbols of the sum of the absolute value of differentially detected I and the absolute value of differentially detected Q. In that case, the first portion of the unique word detection block may comprise a first block for obtaining the absolute value of differentially detected I, a second block for obtaining the absolute value of differentially detected Q, an addition block for adding the absolute value of differentially detected I and the absolute value of differentially detected Q and an accumulation block for performing the summation over K symbols of the sum of the absolute value of differentially detected I and the absolute value of differentially detected Q.

The second factor may equal the sum of the absolute value of averaged I and the absolute value of averaged Q. In that case, the second portion of the unique word detection block may comprise a first block for obtaining the absolute value of averaged I, a second block for obtaining the absolute value of averaged Q and an addition block for adding the absolute value of averaged I and the absolute value of averaged Q.

The comparator may be arranged to calculate the ratio of the first factor to the second factor and compare that ratio with a predetermined value. In that arrangement, the predetermined value may be set by a user. If the ratio is either above or below the predetermined value, the unique word is judged to be present whereas if the ratio is the other of above and below the predetermined value, the unique word is judged not to be present.

The unique word detection block may be arranged, if the unique word has been detected, to determine from the detected unique word, a frequency offset estimation. This frequency offset estimation may be used as the previously estimated value of the frequency offset at the frequency corrector.

According to a second aspect of the invention, there is provided apparatus for performing unique word detection for a receiver for DPSK signals comprising in-phase I and quadrature Q components for a plurality of symbols k, the apparatus being arranged to receive, for each received I and Q, a differentially detected I, a differentially detected Q, a processed form of the received I and a processed form of the received Q, the apparatus comprising:

a first portion for generating a first factor dependent on differentially detected I and differentially detected Q;

a second portion for generating a second factor dependent on processed I and processed Q; and

a comparator for comparing the first factor and the second factor to determine whether a unique word is present in the received signal.

Preferably, the processed I has been generated by the steps of: differential detection of the received signal over a given symbol span; frequency correction of I and Q using a previously estimated value of the frequency offset; and accumulation of I over a given number of symbols K, where K is the number of symbols in the unique word to be detected.

Similarly, preferably, the processed Q has been generated by the steps of: differential detection of the received signal over a given symbol span; frequency correction of I and Q using a previously estimated value of the frequency offset; and accumulation of Q over a given number of symbols K, where K is the number of symbols in the unique word to be detected.

In one embodiment, the first factor is dependent on the square of differentially detected I and the square of differentially detected Q and the second factor is dependent on the square of processed I and the square of processed Q.

The first factor may equal the summation over K symbols of the sum of the square of differentially detected I and the square of differentially detected Q, where K is the number of symbols in the unique word being detected. In that case, the first portion may comprise a first block for squaring differentially detected I, a second block for squaring differentially detected Q, an addition block for adding the square of differentially detected I and the square of differentially detected Q and an accumulation block for performing the summation over K symbols of the sum of the square of differentially detected I and the square of differentially detected Q.

The second factor may equal the sum of the square of processed I and the square of processed Q. In that case, the second portion may comprise a first block for squaring processed I, a second block for squaring processed Q and an addition block for adding the square of processed I and the square of processed Q.

In an alternative embodiment, the first factor is dependent on the absolute value of differentially detected I and the absolute value of differentially detected Q and the second factor is dependent on the absolute value of processed I and the absolute value of processed Q.

The first factor may equal the summation over K symbols of the sum of the absolute value of differentially detected I and the absolute value of differentially detected Q, where K is the number of symbols in the unique word being detected. In that case, the first portion of the unique word detection block may comprise a first block for obtaining the absolute value of differentially detected I, a second block for obtaining the absolute value of differentially detected Q, an addition block for adding the absolute value of differentially detected I and the absolute value of differentially detected Q and an accumulation block for performing the summation over K symbols of the sum of the absolute value of differentially detected I and the absolute value of differentially detected Q.

The second factor may equal the sum of the absolute value of processed I and the absolute value of processed Q. In that case, the second portion of the unique word detection block may comprise a first block for obtaining the absolute value of processed I, a second block for obtaining the absolute value of processed Q and an addition block for adding the absolute value of processed I and the absolute value of processed Q.

Preferably, the comparator is arranged to calculate the ratio of the first factor to the second factor and to compare that ratio with a predetermined value. In that arrangement, the predetermined value may be set by a user. If the ratio is one side of the predetermined value, the unique word is judged to be present whereas if the ratio is the other side of the predetermined value, the unique word is judged not to be present.

According to a third aspect of the invention, there is provided a method for performing unique word detection and frequency offset estimation for received DPSK signals comprising in-phase I and quadrature Q components at a plurality of symbols k, the method comprising the steps of:

a) performing differential detection of a received signal over a given symbol span;

b) performing an initial correction of I and Q using a previously estimated value of the frequency offset; c) averaging I for each symbol k over a given number of symbols K, where K is the number of symbols in the unique word to be detected;

d) averaging Q for each symbol k over the given number of symbols K;

e) calculating an estimate of the frequency offset from averaged I and averaged Q; and

f) determining, from differentially detected I, differentially detected Q, averaged I and averaged Q, whether or not a unique word is present in a received signal.

In this method, steps a), b), c) and d) of differential detection, frequency correction and accumulation are shared between the frequency offset estimation and the unique word detection. The final stages of the frequency offset estimation and the unique word detection are performed at steps e) and f) respectively. Sharing the majority of steps in this way, rather than having a completely separate set of steps for the two processes, greatly simplifies the method.

Typically, the step of performing differential detection over a given symbol span comprises performing differential detection over a symbol span of one symbol.

Preferably, steps c) and d) are carried out in parallel. Preferably, steps e) and f) are carried out in parallel.

Step e) of calculating an estimate of the frequency offset from averaged I and averaged Q may comprise: calculating the angle formed by averaged I and averaged Q; and calculating the estimate of the frequency offset from the angle formed by averaged I and averaged Q. In that case, the step of calculating the angle formed by averaged I and averaged Q may comprise using the arctan function for calculating the angle formed by averaged I and averaged Q. In that case, the step of calculating the angle may be performed using, for example, a CORDIC algorithm or a LUT algorithm.

Because K is the number of unique word symbols, step f) effectively involves looking at each received sequence of K symbols and determining whether or not this sequence matches the unique word.

Preferably, step f) of determining, from differentially detected I, differentially detected Q, averaged I and averaged Q, whether or not a unique word is present in a received signal comprises:

generating a first factor dependent on differentially detected I and differentially detected Q;

generating a second factor dependent on averaged I and averaged Q; and

comparing the first factor and the second factor to determine whether the unique word is present in the received signal.

Preferably, the step of generating the first factor and the step of generating the second factor are carried out in parallel.

In one embodiment, the first factor is dependent on the square of differentially detected I and the square of differentially detected Q and the second factor is dependent on the square of averaged I and the square of averaged Q.

The first factor may equal the summation over K symbols of the sum of the square of differentially detected I and the square of differentially detected Q. In that case, the step of generating the first factor may comprise the steps of squaring differentially detected I, squaring differentially detected Q, adding the square of differentially detected I and the square of differentially detected Q and performing summation over K symbols of the sum of the square of differentially detected I and the square of differentially detected Q. The steps of squaring differentially detected I and squaring differentially detected Q are preferably carried out in parallel.

The second factor may equal the sum of the square of averaged I and the square of averaged Q. In that case, the step of generating the second factor may comprise the steps of squaring averaged I, squaring averaged Q and adding the square of averaged I and the square of averaged Q. The steps of squaring averaged I and squaring averaged Q are preferably carried out in parallel.

In an alternative embodiment, the first factor is dependent on the absolute value of differentially detected I and the absolute value of differentially detected Q and the second factor is dependent on the absolute value of averaged I and the absolute value of averaged Q.

The first factor may equal the summation over K symbols of the sum of the absolute value of differentially detected I and the absolute value of differentially detected Q. In that case, the step of generating the first factor may comprise the steps of obtaining the absolute value of differentially detected I, obtaining the absolute value of differentially detected Q, adding the absolute value of differentially detected I and the absolute value of differentially detected Q and performing summation over K symbols of the sum of the absolute value of differentially detected I and the absolute value of differentially detected Q. The steps of obtaining the absolute value of differentially detected I and obtaining the absolute value of differentially detected Q are preferably carried out in parallel.

The second factor may equal the absolute value of averaged I added to the absolute value of averaged Q. In that case, the step of generating the second factor may comprise the steps of obtaining the absolute value of averaged I, obtaining the absolute value of averaged Q and adding the absolute value of averaged I and the absolute value of averaged Q. The steps of obtaining the absolute value of averaged I and obtaining the absolute value of averaged I are preferably carried out in parallel.

The step of comparing the first factor and the second factor preferably comprises calculating the ratio of the first factor to the second factor and comparing that ratio with a predetermined value. In that arrangement, the predetermined value may be set by a user. If the ratio is either above or below the predetermined value, the unique word is judged to be present whereas, if the ratio is either below or above the predetermined value, the unique word is judged not to be present.

If the unique word has been detected, the method may further comprise the step of, determining from the detected unique word, a frequency offset estimation. This frequency offset estimation may be used as the previously estimated value of the frequency offset at step b) of performing an initial correction of I and Q.

Features described in relation to one aspect of the invention may be applicable to another aspect of the invention.

### BRIEF DESCRIPTION OF THE DRAWINGS

Some known arrangements have already been described with reference to FIGS. 1 to 3 of the accompanying drawings, of which:

FIG. 1 shows the slot structure for a prior art arrangement;

FIG. 2 is a block diagram of a prior art receiver side performing frequency offset error estimation; and

FIG. 3 is a block diagram of a prior art receiver side performing UW detection.

Some exemplary embodiments of the invention will now be described with reference to FIGS. 4 to 6 of the accompanying drawings, of which:

FIG. 4 is a block diagram of the combined UW detection and frequency offset estimation according to an embodiment of the invention;

FIG. 5 shows a first embodiment of block 409 of FIG. 4; and

FIG. 6 shows a second embodiment of block 409 of FIG. 4.

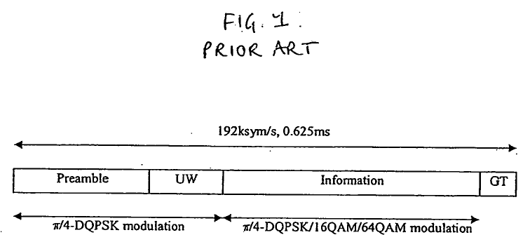

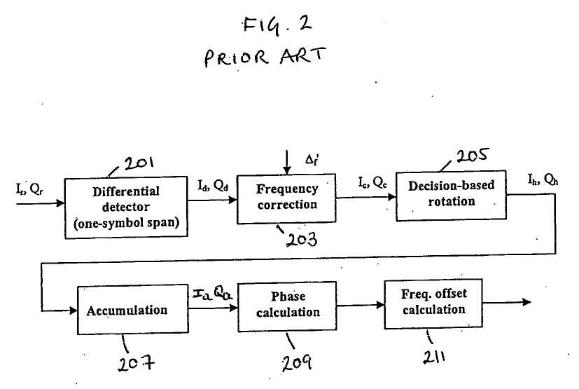

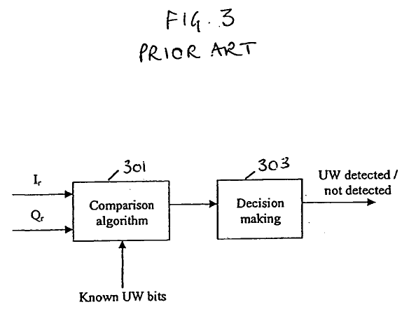

### DETAILED DESCRIPTION OF PREFERRED EMBODIMENTS

According to the invention, the process of frequency offset estimation and UW detection are combined as far as possible. This reduces implementation complexity and implementation delay time.

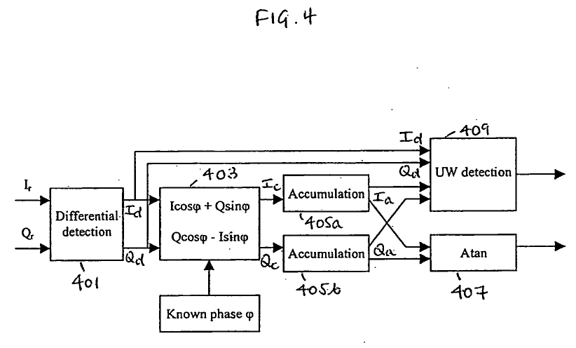

FIG. 4 shows the structure of the combined UW detection and frequency offset estimation according to an embodiment of the invention. Differential detection, frequency correction and accumulation are shared by the frequency offset estimate and UW detection procedures.

The received signal is represented by Iᵣ(k) and Qᵣ(k). I(k) is the in-phase component at symbol k and Q(k) is the quadrature component at symbol k. Block 401 performs differential detection of one symbol span i.e.
I_{d}(k)=Iᵣ(k)Iᵣ(k−1)+Qᵣ(k)Qᵣ(k−1) [1]
Q_{d}(k)=Qᵣ(k)Iᵣ(k−1)−Iᵣ(k)Qᵣ(k−1) [2]

The outputs from the differential detection block 401 are I_{d}(k) and Q_{d}(k).

Block 403 performs phase rotation (equivalent to frequency correction) using a known phase φ_{UW}(k), to produce I_{c}(k) and Q_{c}(k), as follows:
I_{c}(k)=I_{d}(k)cos φ_{UW}+Q_{d}(k)sin φ_{UW} [9]
Q_{c}(k)=Q_{d}(k)cos φ_{UW}−I_{d}(k)sin φ_{UW} [10]
φ_{UW}(k) is the differentially encoded signal phase obtained from a pair of UW bits.
φ_{UW}(0) is obtained from UW bit 0 and UW bit 1
φ_{UW}(1) is obtained from UW bit 1 and UW bit 2,
φ_{UW}(2) is obtained from UW bit 2 and UW bit 3,
and so on.

φ_{UW}(k) takes one of four possible values,

$$\frac{π}{4} , \\ \frac{3 π}{4} , \\ \frac{- 3 π}{4}$$

$$and$$

$$\frac{- π}{4} ,$$

and they are mapped according to the particular encoding convention used. For example, with Gray code:

$$if bit 0 = bit 1 = 0 , {ϕ}_{UW} = \frac{π}{4} , \\ if bit 0 = 1 and bit 1 = 0 , {ϕ}_{UW} = \frac{3 π}{4} , \\ if bit 0 = bit 1 = 1 , {ϕ}_{UW} = \frac{- 3 π}{4} , \\ and$$

$$if bit 0 = 0 and bit 1 = 1 , {ϕ}_{UW} = \frac{- π}{4} .$$

Blocks 405a and 405b perform accumulation. Block 405a receives input I_{c}(k) and outputs Iₐ(k) as follows:

$${I}_{a} = {\sum }_{0}^{K - 1} {I}_{c} \qquad [ 11 ]$$

Block 405b receives input Q_{c}(k) and outputs Qₐ(k) as follows:

$${Q}_{a} = {\sum }_{0}^{K - 1} {Q}_{c} \qquad [ 12 ]$$

Since we are using the blocks 405a and 405b for both frequency offset estimation and UW detection, we set K to be equal to the number of symbols in the unique word. Thus, in the unique word detection block 409, we are effectively looking at each sequence of K symbols in the received message to see whether it matches the UW.

Block 407 performs the final stage for frequency estimation detection and block 409 performs the final stage for UW detection.

Block 407 receives input Iₐ(k) from block 405a and input Qₐ(k) from block 405b and computes the average angle with respect to the x-axis by the arc tan function:

$$arctan [ \frac{{Q}_{a}}{{I}_{a}} ] \qquad [ 7 ]$$

This average angle corresponds to the secondary frequency offset error for fine tuning of the frequency offset. This is a well known procedure and may be performed by a CORDIC (Coordinate Rotation Digital Computer) algorithm, by a Look Up Table (LUT) algorithm or by any other suitable algorithm.

Block 409 receives input Iₐ(k) from block 405a, input Qₐ(k) from block 405b and I_{d}(k) and Q_{d}(k) i.e. the originally received signal in-phase and quadrature components after differential detection. The UW detection may be performed in a number of ways.

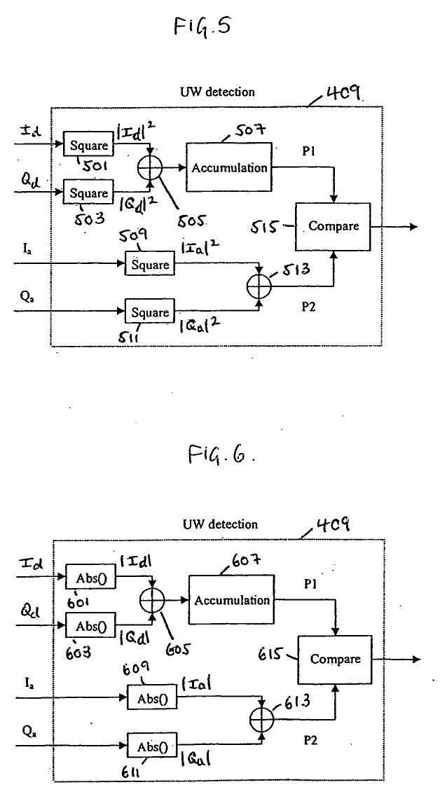

A first embodiment of UW detection is shown in FIG. 5. In this embodiment P1(k) and P2(k) are computed and compared to decide whether the particular sequence of K symbols (=number of UW symbols) matches the UW. P1(k) is the average power of the set of symbols and it functions as a normalizer. P2(k) is a measure of the deviation of the K input symbols from the UW symbols. Or, putting it another way, P2(k) can be thought of as a measure of the correlation between the set of input symbols and the unique word.

In this arrangement

$$\begin{matrix}P 1 ( k ) = {\sum }_{k}^{K - 1 + k} {\vert {I}_{d} \vert}^{2} + {\vert {Q}_{d} \vert}^{2} & [ 13 ] \\ P 2 ( k ) = {\vert {\sum }_{k}^{K - 1 + k} {I}_{c} \vert}^{2} + {\vert {\sum }_{k}^{K - 1 + k} {Q}_{c} \vert}^{2} & [ 14 ]\end{matrix}$$

From equations [11] and [12], we see that P2(k) is dependent on Iₐ and Qₐ.

If the set of input symbols matches the UW and the quality of the input symbols is perfect (i.e. no noise, no frequency offset) I_{c}(k)=1 and Q_{c}(k)=0 and P2(k)=K². If the symbols do not match, P2(k) is less than K².

We see from equations [3] and [4] that I_{c}(k) is actually the instantaneous estimation of cos(Δf) and Q_{c}(k) is actually the instantaneous estimation of sin(Δf).

$$P 1 ( 0 ) = {\sum }_{0}^{K - 1} {\vert {I}_{d} \vert}^{2} + {\vert {Q}_{d} \vert}^{2} and P 2 ( 0 ) = {\vert {\sum }_{0}^{K - 1} {I}_{c} \vert}^{2} + {\vert {\sum }_{0}^{K - 1} {Q}_{c} \vert}^{2}$$

$$and P 1 ( 1 ) = {\sum }_{1}^{K} {\vert {I}_{d} \vert}^{2} + {\vert {Q}_{d} \vert}^{2} and P 2 ( 1 ) = {\vert {\sum }_{1}^{K} {I}_{c} \vert}^{2} + {\vert {\sum }_{1}^{K} {Q}_{c} \vert}^{2}$$

and so on.

Thus, P1(k) depends solely on the received signal components after differential detection I_{d} and Q_{d}, whereas P2(k) depends on the components Iₐ and Qₐ i.e. the components outputted from the accumulation blocks 405a and 405b.

If the set of symbols matches the UW perfectly and there is no noise and no frequency offset (i.e. the ideal limit),

$$\frac{P 2 ( k )}{P 1 ( k )} = \frac{K}{power}$$

where power is the transmitted power per symbol. i.e.

$$\frac{K}{power}$$

is the theoretical maximum of

$$[ \frac{P 2 ( k )}{P 1 ( k )} ] .$$

Obviously, in practice,

$$[ \frac{P 2 ( k )}{P 1 ( k )} ]$$

is less than this, but we set threshold A

$$( with 0 < A < \frac{K}{power} )$$

such that, if

$$[ \frac{P 2 ( k )}{P 1 ( k )} ]$$

exceeds A, the UW is judged as power P1(k) detected. Thus, the higher A is set, the stricter the detection requirement, since

$$[ \frac{P 2 ( k )}{P 1 ( k )} ]$$

then has to be closer to its theoretical maximum before the UW is detected i.e. the input symbols need to match the UW symbols very closely and be almost free of noise and frequency offset.

Once the UW sequence is successfully detected, the frequency offset estimation can be obtained from those input symbols which have satisfied the detection requirement and used at block 403 (in known phase φ=2πΔ_{f}′k) to improve the frequency offset estimation.

Referring to FIG. 5, P1(k) is calculated in the upper portion of UW detection block 409 and P2(k) is calculated in the lower portion of UW detection block 409. I_{d}, Q_{d}, Iₐ and Qₐ are received in the UW detection block.

Referring to the upper portion, |I_{d}|² is calculated at block 501 and |Q_{d}|² is calculated at block 503. At addition block 505, |I_{d}|² and |Q_{d}|² are added together and, at accumulation block 507, P1(k) is calculated, according to equation [13].

Referring to the lower portion, |Iₐ|² is calculated at block 509 and |Q_{d}|² is calculated at block 511. P2(k) is calculated, according to equation [14] at addition block 513.

Comparison block 515 compares P1(k) and P2(k) to decide whether the UW is detected or not.

A second embodiment of UW detection is shown in FIG. 6. Again, in this embodiment P1(k) and P2(k) are computed and compared to decide whether the particular sequence of K symbols matches the UW. In this arrangement

$$\begin{matrix}P 1 ( k ) = {\sum }_{k}^{K - 1 + k} \{ \vert {I}_{d} \vert + \vert {Q}_{d} \vert \} & [ 15 ] \\ P 2 ( k ) = \vert {\sum }_{k}^{K - 1 + k} {I}_{c} \vert + \vert {\sum }_{k}^{K - 1 + k} {Q}_{c} \vert & [ 16 ]\end{matrix}$$

From equations [11] and [12], we see that P2(k) is dependent on Iₐ and Qₐ.

$$Thus , P 1 ( 0 ) = {\sum }_{0}^{K - 1} \{ \vert {I}_{d} \vert + \vert {Q}_{d} \vert \} and P 2 ( 0 ) = \vert {\sum }_{0}^{K - 1} {I}_{c} \vert + \vert {\sum }_{0}^{K - 1} {Q}_{c} \vert$$

$$and P 1 ( 1 ) = {\sum }_{1}^{K} \{ \vert {I}_{d} \vert + \vert {Q}_{d} \vert \} and P 2 ( 1 ) = \vert {\sum }_{1}^{K} {I}_{c} \vert + \vert {\sum }_{1}^{K} {Q}_{c} \vert$$

so on.

Thus, as with the first embodiment, P1(k) depends solely on the differentially detected received signal components I_{d} and Q_{d}, whereas P2(k) depends on the components Iₐ and Qₐ i.e. the components outputted from the accumulation blocks 405a and 405b.

Referring to FIG. 6, P1(k) is calculated in the upper portion of UW detection block 409 and P2(k) is calculated in the lower portion of UW detection block 409. I_{d}, Q_{d}, Iₐ and Qₐ are received in the UW detection block.

Referring to the upper portion, the absolute value of I_{d}, |I_{d}| is obtained at block 601 and the absolute value of Q_{d}, |Q_{d}| is obtained at block 603. At addition block 605, |I_{d}| and |Q_{d}| are added together and, at accumulation block 607 P1(k) is calculated, according to equation [15].

Referring to the lower portion, |Iₐ| is obtained at block 609 and |Qₐ| is obtained at block 611. P2(k) is calculated, according to equation [16], at addition block 613.

Comparison block 615 compares P1(k) and P2(k) to decide whether the UW is detected or not.

As with the first embodiment, as long as

$$[ \frac{P 2 ( k )}{P 1 ( k )} ]$$

exceeds a certain threshold A′. the UW is judged as detected. In this embodiment, the theoretical maximum of

$$[ \frac{P 2 ( k )}{P 1 ( k )} ] is \frac{1}{\sqrt{2 xpower}}$$

so A′ satisfies

$$0 < {A}^{′} < \frac{1}{\sqrt{2 xpower}} .$$

Within these limits, A′ an be set appropriately, depending on how strict a detection is required.

Once again, the frequency offset estimation obtained from the successfully detected UW can be used at block 403 to improve the frequency offset estimation.

Two particular ways of detecting UW have been described with reference to FIGS. 5 and 6, but the invention is not limited to one or other of those embodiments.

1. Apparatus for performing unique word detection and frequency offset estimation for a receiver for DPSK signals comprising in-phase I and quadrature Q components for a plurality of symbols k, the apparatus comprising:
a differential detector for performing differential detection of a received signal over a given symbol span;
a frequency corrector for performing an initial correction of I and Q using a previously estimated value of the frequency offset;
an accumulator for averaging I for each symbol k over a given number K of symbols, where K is the number of symbols in the unique word to be detected;
an accumulator for averaging Q for each symbol k over the given number K of symbols;
a frequency offset estimation block for calculating an estimate of the frequency offset from averaged I and averaged Q; and
a unique word detection block for determining, from differentially detected I, differentially detected Q, averaged I and averaged Q, whether or not the unique word is present in a received signal.

2. Apparatus according to claim 1 wherein the frequency offset estimation block comprises:
a computation block for calculating the angle formed by averaged I and averaged Q; and
a frequency offset calculation block for calculating the estimate of the frequency offset from the angle formed by averaged I and averaged Q.

3. Apparatus according to claim 2 wherein the computation block performs the arctan function for calculating the angle formed by averaged I and averaged Q.

4. Apparatus according to claim 1 wherein the unique word detection block comprises:
a first portion for generating a first factor dependent on differentially detected I and differentially detected Q;
a second portion for generating a second factor dependent on averaged I and averaged Q; and
a comparator for comparing the first factor and the second factor to determine whether the unique word is present in the received signal.

5. Apparatus according to claim 4 wherein the first factor is dependent on the square of differentially detected I and the square of differentially detected Q and the second factor is dependent on the square of averaged I and the square of averaged Q.

6. Apparatus according to claim 5 wherein the first factor equals the summation over K symbols of the sum of the square of differentially detected I and the square of differentially detected Q.

7. Apparatus according to claim 5 wherein the second factor equals the sum of the square of averaged I and the square of averaged Q.

8. Apparatus according to claim 4 wherein the first factor is dependent on the absolute value of differentially detected I and the absolute value of differentially detected Q and the second factor is dependent on the absolute value of averaged I and the absolute value of averaged Q.

9. Apparatus according to claim 8 wherein the first factor equals the summation over K symbols of sum of the absolute value of differentially detected I and the absolute value of differentially detected Q.

10. Apparatus according to claim 8 wherein the second factor equals the sum of the absolute value of averaged I and the absolute value of averaged Q.

11. Apparatus according to claim 4 wherein the comparator is arranged to calculate the ratio of the first factor to the second factor and compare that ratio with a predetermined value.

12. Apparatus for performing unique word detection for a receiver for DPSK signals comprising in-phase I and quadrature Q components for a plurality of symbols k, the apparatus being arranged to receive, for each received I and Q, a differentially detected I, a differentially detected Q, a processed form of the received I and a processed form of the received Q, the apparatus comprising:
a first portion for generating a first factor dependent on differentially detected I and differentially detected Q;
a second portion for generating a second factor dependent on processed I and processed Q; and
a comparator for comparing the first factor and the second factor to determine whether a unique word is present in the received signal.

13. Apparatus according to claim 12 wherein the first factor is dependent on the square of differentially detected I and the square of differentially detected Q and the second factor is dependent on the square of processed I and the square of processed Q.

14. Apparatus according to claim 13 wherein the first factor equals the summation over K symbols of the sum of the square of differentially detected I and the square of differentially detected Q, where K is the number of symbols in the unique word being detected.

15. Apparatus according to claim 13 wherein the second factor equals the sum of the square of processed I and the square of processed Q.

16. Apparatus according to claim 12 wherein the first factor is dependent on the absolute value of differentially detected I and the absolute value of differentially detected Q and the second factor is dependent on the absolute value of processed I and the absolute value of processed Q.

17. Apparatus according to claim 8 wherein the first factor equals the summation over K symbols of the sum of the absolute value of differentially detected I and the absolute value of differentially detected Q, where K is the number of symbols in the unique word being detected.

18. Apparatus according to claim 16 wherein the second factor equals the sum of the absolute value of processed I and the absolute value of processed Q.

19. Apparatus according to claim 12 wherein the comparator is arranged to calculate the ratio of the first factor to the second factor and to compare that ratio with a predetermined value.

20. A method for performing unique word detection and frequency offset estimation for received DPSK signals comprising in-phase I and quadrature Q components at a plurality of symbols k, the method comprising the steps of:
a) performing differential detection of a received signal over a given symbol span;
b) performing an initial correction of I and Q using a previously estimated value of the frequency offset;
c) averaging I for each symbol k over a given number of symbols K, where K is the number of symbols in the unique word to be detected;
d) averaging Q for each symbol k over the given number of symbols K;
e) calculating an estimate of the frequency offset from averaged I and averaged Q; and
f) determining, from differentially detected I, differentially detected Q, averaged I and averaged Q, whether or not a unique word is present in a received signal.

21. A method according to claim 20 wherein steps c) and d) are carried out in parallel.

22. A method according to claim 20 wherein steps e) and f) are carried out in parallel.

23. A method according to claim 20 wherein step e) of calculating an estimate of the frequency offset from averaged I and averaged Q comprises:
calculating the angle formed by averaged I and averaged Q; and
calculating the estimate of the frequency offset from the angle formed by averaged I and averaged Q.

24. A method according to claim 23 wherein the step of calculating the angle formed by averaged I and averaged Q comprises using the arctan function for calculating the angle formed by averaged I and averaged Q.

25. A method according to claim 20 wherein step f) of determining, from differentially detected I, differentially detected Q, averaged I and averaged Q, whether or not a unique word is present in a received signal comprises:
generating a first factor dependent on differentially detected I and differentially detected Q;
generating a second factor dependent on averaged I and averaged Q; and
comparing the first factor and the second factor to determine whether the unique word is present in the received signal.

26. A method according to claim 25 wherein the step of generating the first factor and the step of generating the second factor are carried out in parallel.

27. A method according to claim 25 wherein the first factor is dependent on the square of differentially detected I and the square of differentially detected Q and the second factor is dependent on the square of averaged I and the square of averaged Q.

28. A method according to claim 27 wherein the first factor equals the summation over K symbols of the sum of the square of differentially detected I and the square of differentially detected Q.

29. A method according to claim 27 wherein the second factor equals the sum of the square of averaged I and the square of averaged Q.

30. Apparatus according to claim 25 wherein the first factor is dependent on the absolute value of differentially detected I and the absolute value of differentially detected Q and the second factor is dependent on the absolute value of averaged I and the absolute value of averaged Q.

31. A method according to claim 30 wherein the first factor equals the summation over K symbols of the sum of the absolute value of differentially detected I and the absolute value of differentially detected Q.

32. A method according to claim 30 wherein the second factor equals the absolute value of averaged I added to the absolute value of averaged Q.

33. A method according to claim 25 wherein the step of comparing the first factor and the second factor comprises calculating the ratio of the first factor to the second factor and comparing that ratio with a predetermined value.
